(19) United States
(12) Patent Application Publication
(10) Pub. No.: US 2011/0006339 A1
(43) Pub. Date: Jan. 13, 2011

(54) SEMICONDUCTOR DEVICE AND METHOD OF MANUFACTURING THE SAME

(75) Inventors: Kaoru UCHIDA, Toyama (JP); Kazuyuki SAWADA, Osaka (JP); Yuji HARADA, Toyama (JP)

Correspondence Address: GREENBLUM & BERNSTEIN, P.L.C., 1950 ROLAND CLARKE PLACE, RESTON, VA, 20191, US

(73) Assignee: PANASONIC CORPORATION, Osaka (JP)

(21) Appl. No.: 12/828,422

(22) Filed: Jul. 1, 2010

(30) Foreign Application Priority Data
Jul. 9, 2009 (JP) 2009-163115

(51) Int. Cl. H01L 29/739; H01L 21/331

(52) U.S. Cl. 257/141; 438/135; 257/288; 438/197; 257/E21.382; 257/E29.197

(57) ABSTRACT

A lateral hybrid IGBT is provided including: a RESURF region which is an n-type dopant layer formed in a surface portion of a substrate 1 made of p-type Si; a base region which is a p-type dopant layer; an emitter/source region which is an n-type dopant layer with a high concentration; a collector region which is a p-type dopant layer with a low concentration and formed in the RESURF region; a drain region which is an n-type dopant layer with a high concentration and formed adjacent to the collector region but on another cross-section; a base connection region which is a p-type dopant layer with a high concentration; a gate insulator film; and a gate electrode, wherein the collector region is shallower than the drain region located on the other cross-section.

### BACKGROUND OF THE INVENTION

(1) Field of the Invention

The present invention relates to a semiconductor device and particularly to a high voltage semiconductor switching device which is used in a switching power supply and repeatedly turns on and off to control conduction of main current.

(2) Description of the Related Art

Semiconductor power devices in power conversion equipment, power controller, etc., widely use switching devices such as high voltage MOS transistors for switching between conduction and non-conduction of current. In the application with high output, the on-state voltage drop needs to be small to reduce power loss as much as possible, and therefore suitable is an insulated gate bipolar transistor (hereinafter referred to as “IGBT”) with conductivity modulation.

The following describes structure and operation of a lateral IGBT as a conventional example (refer to Japanese Unexamined Patent Application Publications No. 8-340101 and No. 2005-109394, for example).

FIG. 1 illustrates a cross-section structure of the lateral IGBT of a conventional design, formed on a semiconductor substrate.

As shown in FIG. 1, in a surface layer of a substrate 201 made of p-type silicon (Si), an n-type dopant layer is formed as a RESURF region 202. In part of the surface layer of the substrate 201, a p-type dopant layer is formed as a base region 204. Furthermore, in part of a surface layer of the base region 204, an n-type dopant layer with a higher concentration than the RESURF region 202 is formed as an emitter/source region 205. On the surface of the base region 204 between the RESURF region 202 and the emitter/source region 205, a gate insulator film 206 is formed on which a gate electrode 207 made of polysilicon is formed. In the surface layer of the base region 204, a p-type dopant layer with a higher concentration than the base region 204 is formed as a contact region 208. In part of a surface layer of the RESURF region 202, a p-type dopant layer is formed as a collector region 211.

In the lateral IGBT shown in FIG. 1, the substrate 201 is irradiated with protons or helium ions so that the irradiation damage creates a damaged region 220. This damaged region 220 controls a life time of carriers to cut down the turn-off time.

FIG. 2 illustrates a cross-section structure of the lateral IGBT of a conventional design, formed on a semiconductor substrate.

As shown in FIG. 2, in a surface layer of a substrate 301 made of p-type silicon (Si), an n-type dopant layer is formed as a RESURF region 302. In part of the surface layer of the substrate 301, a p-type dopant layer is formed as a base region 304. Furthermore, in part of a surface layer of the base region 304, an n-type dopant layer with a higher concentration than the RESURF region 302 is formed as an emitter/source region 305. On the surface of the base region 304 between the RESURF region 302 and the emitter/source region 305, a gate insulator film 306 is formed on which a gate electrode 307 made of polysilicon is formed. In the surface layer of the RESURF region 302, p-type dopant layers are formed as contact regions 311.

In the lateral IGBT shown in FIG. 2, a p-type insulated gate transistor is additionally provided within the RESURF region 302 so that a short circuit is created between the base and the emitter. This p-type insulated gate transistor is constituted by a collector region 311 selectively formed in an upper part of the RESURF region 302 and a gate electrode formed, via the gate insulator film, on the RESURF region 302 between the collector regions 311, and is turned on when the lateral IGBT is turned off, thereby cutting down the turn-off time.

However, in the case of the conventional example shown in FIG. 1, the irradiation damage of the substrate creates damage in the interface between the base region and the gate insulator film which are present on the surface of the semiconductor substrate. This damage in the interface between the base region and the gate insulator film will cause leakage of current. Moreover, in order to irradiate the substrate, special manufacturing facility and technique are required.

In the case of the conventional example shown in FIG. 2, because the p-type insulated gate transistor is additionally provided to create a short circuit between the base and the emitter, a chip area will increase and a production cost will rise.

### SUMMARY OF THE INVENTION

In view of the above problems, an object of the present invention is to provide a high voltage semiconductor power device and a method of manufacturing the same, which are able to improve a switching speed, without adding a manufacturing step of creating damage in an interface between a base region and a gate insulator film, which damage causes leakage of current, and without adding an extra device which leads to an increase in a chip area.

In order to achieve the above object, the semiconductor device according to an aspect to the present invention includes: a semiconductor substrate of a first conductivity type; a RESURF region of a second conductivity type formed in a surface portion of the semiconductor substrate; a base region of the first conductivity type formed in the semiconductor substrate so as to be adjacent to the RESURF region; an emitter/source region of the second conductivity type formed in the base region so as to be isolated from the RESURF region; a base connection region of the first conductivity type formed in the base region so as to be adjacent to the emitter/source region; a gate insulator film formed on and across the emitter/source region, the base region, and the RESURF region; a gate electrode formed on the gate insulator film; a drain region of the second conductivity type formed in the RESURF region so as to be isolated from the base region; a collector region of the first conductivity type formed in the RESURF region so as to be isolated from the base region and adjacent to the drain region; a collector/drain electrode formed above the semiconductor substrate and electrically coupled to both of the collector region and the drain region; and an emitter/source electrode formed above the semiconductor substrate and electrically coupled to both of the base connection region and the emitter/source region, wherein the collector region is shallower than the drain region.

The semiconductor according to an aspect of the present invention is capable of performing the MOSFET operation when the collector current flowing through the device is relatively low, and capable of performing the IGBT operation when the collector current flowing through the device is high, thus allowing one device to selectively use two kinds of operation: the MOSFET operation and the IGBT operation.

The MOSFET has a property of turning on/off rapidly while the IGBT has a property of rising more slowly than the MOSFET. In the semiconductor device according to the present invention, upon turning on the semiconductor device in off-state, the excess carriers present in the RESURF region are recombined in the drain region deeper than the collector region, and this accelerated carrier extinction contributes to an increase in a current fall speed.

In the semiconductor device according to an aspect of the present invention, the collector region preferably has a dopant concentration of 1.0×10¹⁷ cm⁻³ or less and a depth of 0.7 μm or less.

Thus, because the collector region serves as a source of the carriers to be injected in on-state, forming a shallow collector region with a low concentration will suppress generation of excess carriers and therefore lead to a further increase in the current fall speed.

In the semiconductor device according to the present invention, it is preferable that neither the RESURF region nor the semiconductor substrate have lattice damage for controlling a carrier life time.

This makes it possible to distinctly reduce occurrence of the leakage of current which is attributed to the damage created in the interface between the base region and the gate insulator film due to the irradiation damage. This is because, in the RESURF region within which the collector region having a low concentration and being shallower than the drain region is formed, the carrier extinction through recombination is accelerated, leading to an increase in the current fall speed, and therefore, even without the lattice damage for controlling the life time of the carriers, it is possible to attain an equivalent fall speed.

A method of manufacturing a semiconductor device according to an aspect of the present invention includes: forming a RESURF region of a second conductivity type in a desired region in a surface of a semiconductor substrate of a first conductivity type; forming a base region of a first conductivity type in the semiconductor substrate so as to be adjacent to the RESURF region; laminating a gate insulator film and a gate electrode on part of the RESURF region and the base region; forming an emitter/source region of the second conductivity type in a portion which is included in the base region and adjacent to the gate electrode; forming a base connection region of the first conductivity type in a portion which is included in the base region and adjacent to the emitter/source region; forming a drain region of the second conductivity type in a portion which is included in the RESURF region and isolated from the base region; diffusing the drain region by a heat treatment; forming a collector region of the first conductivity type in a portion which is included in the RESURF region, isolated from the base region, and adjacent to the drain region; forming a collector/drain electrode so as to be electrically coupled to both of the collector region and the drain region; and forming an emitter/source electrode so as to be electrically coupled to both of the base connection region and the emitter/source region, wherein the collector region is formed to be shallower than the drain region.

In the method of manufacturing the semiconductor device according to an aspect of the present invention, the collector region is formed to be shallow, which suppresses generation of excess carriers when the semiconductor device is in on-state and which accelerates the carrier extinction through recombination because of the drain region deeper than the collector region when the semiconductor device is turned off, so that the current fall speed can be increased. It is thus possible to provide the fast switching semiconductor device.

The present invention provides a semiconductor device which has a low on-resistance and a high withstand voltage and is capable of fast switching with a semiconductor substrate having no lattice damage for controlling a life time of carriers.

### FURTHER INFORMATION ABOUT TECHNICAL BACKGROUND TO THIS APPLICATION

The disclosure of Japanese Patent Application No. 2009-163115 filed on Jul. 9, 2009 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a structural cross-section view of a conventional semiconductor device;

FIG. 2 is a structural cross-section view of a conventional semiconductor device;

FIG. 3 is a structural plan view showing one example of a semiconductor device according to the first embodiment of the present invention;

FIG. 4 is a structural cross-section view taken along the line A-A′ of FIG. 3;

FIG. 5 is a structural cross-section view taken along the line B-B′ of FIG. 3;

FIG. 6 is a graph showing I-V characteristics of the semiconductor device according to the first embodiment of the present invention;

FIG. 7 is a graph showing a fall time of IGBT depending on a depth and a concentration of a collector region;

FIG. 8 is a structural cross-section view showing another example of the semiconductor device according to the first embodiment of the present invention;

FIG. 9 is a cross-section view of a semiconductor device in a manufacturing process according to the second embodiment of the present invention;

FIG. 10 is a cross-section view of the semiconductor device in a manufacturing process according to the second embodiment of the present invention;

FIG. 11 is a cross-section view of the semiconductor device in a manufacturing process according to the second embodiment of the present invention;

FIG. 12 is a cross-section view of the semiconductor device in a manufacturing process according to the second embodiment of the present invention;

FIG. 13 is a cross-section view of the semiconductor device in a manufacturing process according to the second embodiment of the present invention;

FIG. 14 is a cross-section view of the semiconductor device in a manufacturing process according to the second embodiment of the present invention;

FIG. 15 is a cross-section view of the semiconductor device in a manufacturing process according to the second embodiment of the present invention;

FIG. 16 is a cross-section view of the semiconductor device in a manufacturing process according to the second embodiment of the present invention; and

FIG. 17 is a cross-section view of the semiconductor device in a manufacturing process according to the second embodiment of the present invention.

### DESCRIPTION OF THE PREFERRED EMBODIMENT(S)

### First Embodiment

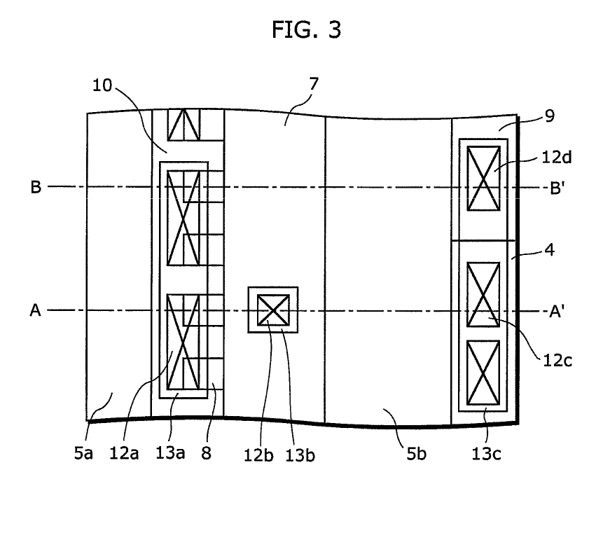

With reference to FIGS. 3 to 5, the first embodiment of the semiconductor device according to the first embodiment will be described.

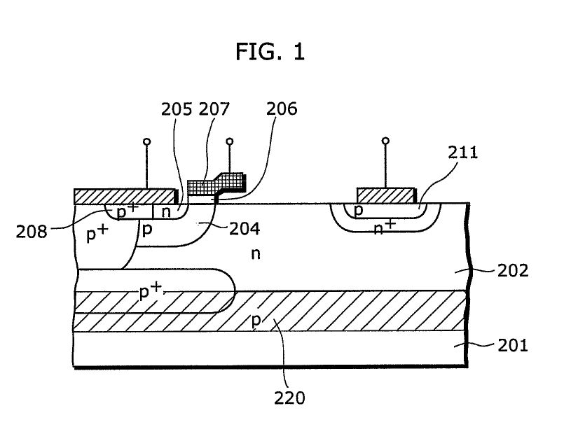

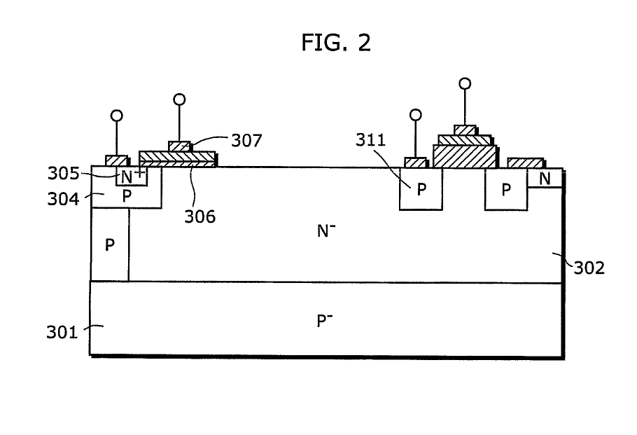

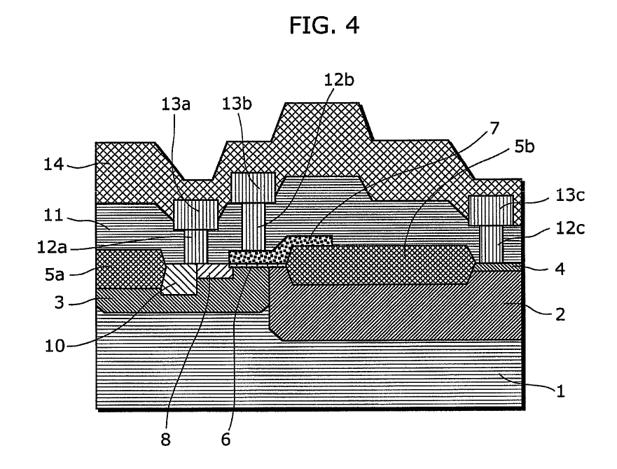

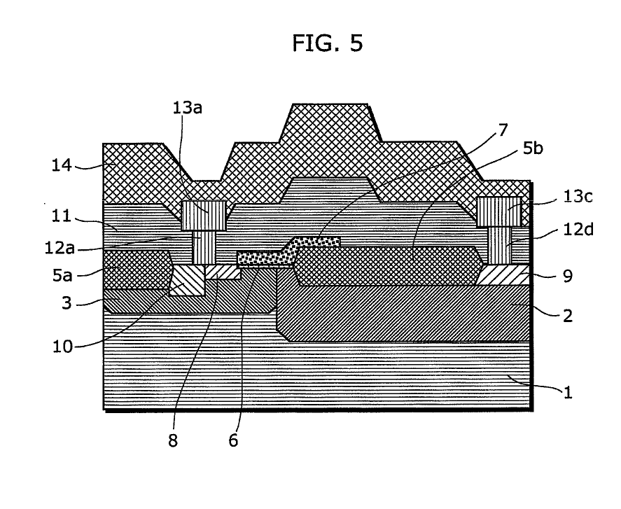

FIG. 3 is a plan view of the semiconductor device according to the first embodiment. FIG. 4 is a cross-section view of the structure taken along the line A-A′ of FIG. 1. FIG. 5 is a cross-section view of the structure taken along the line B-B′ of FIG. 3. FIGS. 3 to 5 show one example of a power transistor which has a RESURF region with a low concentration and integrates characteristics of a lateral MOSFET and a lateral IGBT.

The semiconductor device according to the first embodiment includes a substrate 1, a RESURF region 2, a base region 3, a collector region 4, a gate insulator film 6, a gate electrode 7, insulator films 5a and 5b, an emitter/source region 8, a drain region 9, a base connection region 10, an inter-layer insulator film 11, contact holes 12a, 12b, 12c, and 12d, electrodes 13a, 13b, and 13c, and a protective film 14. The substrate 1 is made of p-type Si and has a concentration in the order of 1E14 cm⁻³ and a thickness of 200 μm to 400 μm. The RESURF region 2 is an n-type dopant layer having a thickness in the order of 3 μm to 5 μm from a surface of the substrate 1 and having a concentration in the order of 1E16 cm⁻³ to 5E16 cm⁻³. The base region 3 is a p-type dopant layer having a concentration in the order to 1E17 cm⁻³, formed in the proximity of the surface of the substrate 1 where the RESURF region 2 is not formed. The collector region 4 is a p-type dopant layer with a low concentration in the order to 2E16 cm⁻³ to 1E17 cm⁻³, formed at a depth in the order of 0.4 μm to 0.7 μm from a surface level of the RESURF region 2 (FIG. 4). The gate insulator film 6 is made of SiO₂ and formed on and across the RESURF region 2 and the base region 3. The gate electrode 7 is a poly-Si film formed on the gate insulator film 6. The insulator films 5a and 5b are made of SiO₂, which separates transistors formed on the substrate 1. The emitter/resource region 8 is an n-type dopant layer having a concentration in the order of 1E18 cm⁻³ to 1E20 cm⁻³, formed in the base region 3. The drain region 9 is an n-type dopant layer with a high concentration in the order of 1E18 cm⁻³ to 1E20 cm⁻³, formed at a depth in the order of 0.8 μm from a surface level of the RESURF region 2 (FIG. 5). The base connection layer 10 is a p-type dopant layer having a concentration in the order of 1E18 cm⁻³ to 1E19 cm⁻³, formed adjacent to the emitter/source region 8 in the base region 3. The inter-layer insulator film 11 is a laminate film of a SiO₂ film and a boron phosphor silicate glass (BPSG) film for separating the gate electrode 7 from the electrode 13a connected to the emitter/source region 8. The contact holes 12a, 12b, 12c, and 12d are formed in the inter-layer insulator film 11 and respectively located on the boundary between the emitter/source region 8 and the base connection region 10, on the gate electrode 7, on the collector region 4, and on the drain region 9. The electrodes 13a, 13b, and 13c are made of aluminum alloy. The protective film 14 is made of SiN. The electrode 13a is connected, via the contact hole 12a, to the boundary region of the emitter/source region 8 and the base connection region 10. The electrode 13b is connected, via the contact hole 12b, to the gate electrode 7. The electrode 13c is connected, via the contact holes 12c and 12d, to both of the collector region 4 and the drain region 9.

The A-A′ cross-section shown in FIG. 4 is a structure of the lateral IGBT while the B-B′ cross-section shown in FIG. 5 is a structure of the lateral MOSFET.

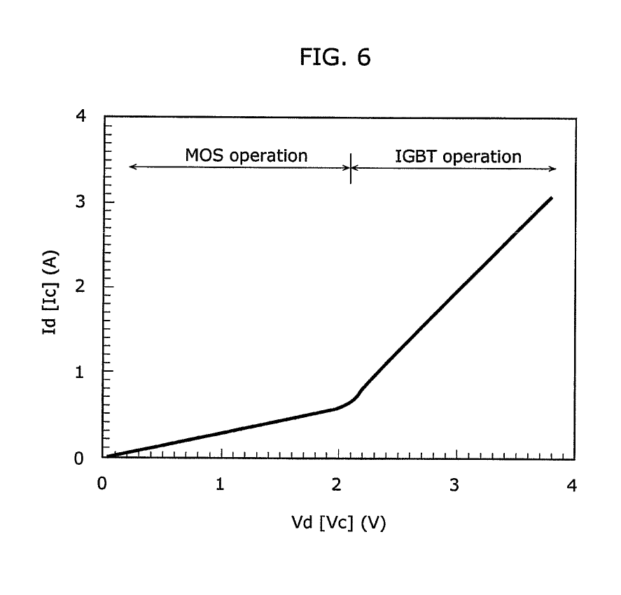

As seen in the example of I-V characteristics of this device shown in FIG. 6, on the lower voltage side than approximately 2.2 V, is the voltage rises rapidly as the device performs the operation of MOS transistor and on the higher voltage side than approximately 2.2 V, the current is high as the device performs the operation of IGBT.

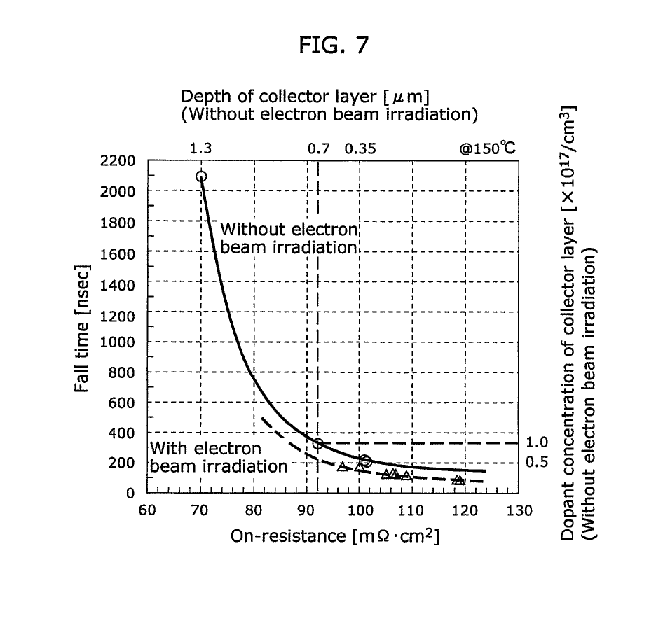

The collector region 4, which is a p-type dopant layer with a low concentration, is formed so as to have a low concentration in the order of 1E17 cm⁻³ or lower at a depth in the order of 0.4 μm to 0.7 μm, which is shallower than the drain region 9 that is an n-type dopant layer formed at a depth of 0.8 μm with a high concentration. This not only suppresses generation of excess carriers when the semiconductor device is in on-state, but also accelerates carrier extinction through recombination by the drain region 9, which is deeper than the collector region 4, when the semiconductor device is turned off, with the result that a current fall speed can be improved to be as high as the current fall speed of the IGBT having damage created by electron beam irradiation as seen in the example of fall time (tf)-on-resistance (Ron) characteristics shown in FIG. 7.

Thus, providing the collector region 4 having a low concentration in the order of 1E17 cm⁻³ or less and furthermore being shallower than the drain region 9 will improve the current fall speed, which eliminates the need for lattice damage which is created by electron beam irradiation to control a life time of carriers.

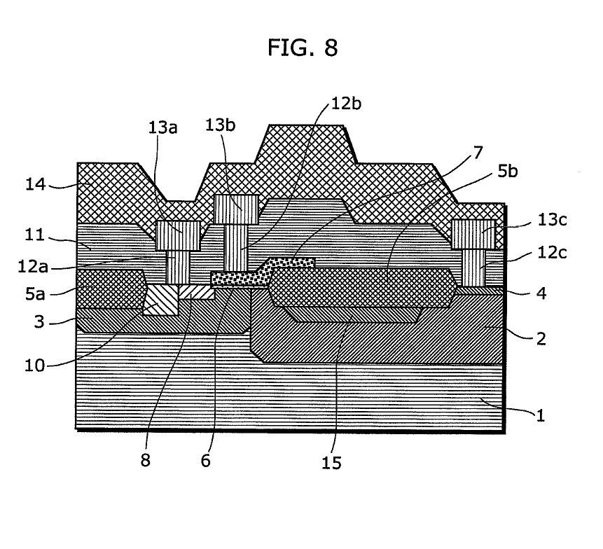

Although the RESURF structure in the example shown in FIGS. 3 to 5 is simple, the RESURF region 2 may include a p-type dopant layer 15 with a low concentration in the order of 2E16 cm⁻³ to 1E17 cm⁻³ as shown in FIG. 8. In this case, the RESURF region 2 is vertically sandwiched between the p-type dopant layers and therefore more easily depleted, which means that the n-type dopant concentration of the RESURF region 2 can be made higher than that of the RESURF region 2 with a simple structure shown in FIGS. 3 to 5 to attain the same withstand voltage. Accordingly, when the IGBT is turned off, holes in the RESURF region 2 can disappear in a shorter time, which leads to a further increase in the fall speed.

### Second Embodiment

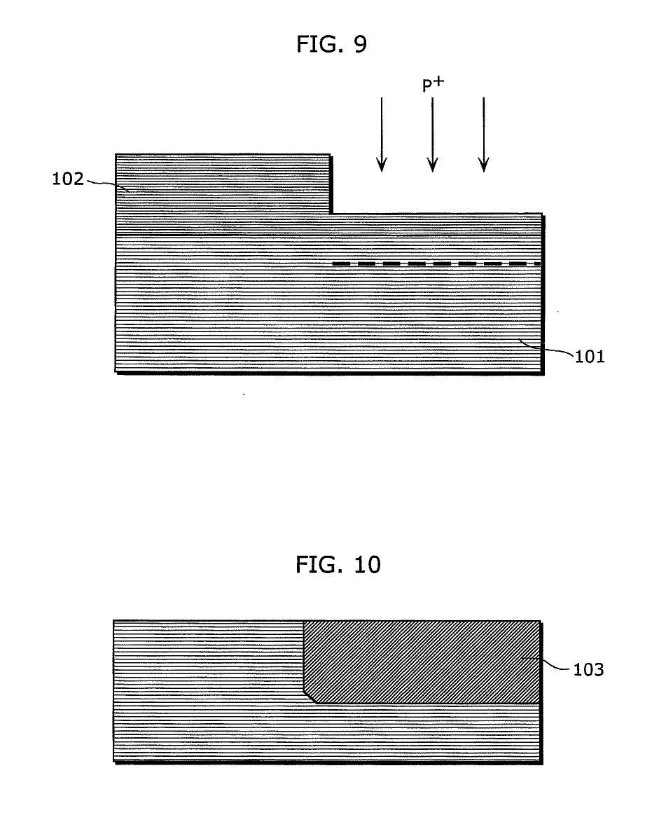

FIGS. 9 to 17 are cross-section views of the semiconductor device in a manufacturing process according to an aspect of the present invention, illustrating steps of manufacturing a power transistor having a lateral IGBT structure with a low-concentration RESURF region.

First, as shown in FIG. 9, an SiO₂ film 102 is formed in a surface layer of a substrate 101 made of p-type Si with a thickness in the order of 500 μm to 650 μm and a concentration in the order of 1E14 cm⁻³. Then, in a desired region, a resist pattern (not shown) is formed as a mask for etching the SiO₂ film. By removing the resist, the SiO₂ film 102 can be patterned in a desired shape. Subsequently, using the patterned SiO₂ film 102 as a mask, P ions are implanted to the depth indicated by a dashed line in FIG. 9. The dose of the P ions is in the order of 1E12 cm⁻² E13 cm⁻².

The structure is then treated with heat in a nitrogen atmosphere of approximately 1,200° C. for around three to six hours, thereby forming as a RESURF region an n-type dopant layer 103 having a concentration in the order to 1E16 cm⁻³ to 5E16 cm⁻³ and a thickness in the order of 5 μm as shown in FIG. 10.

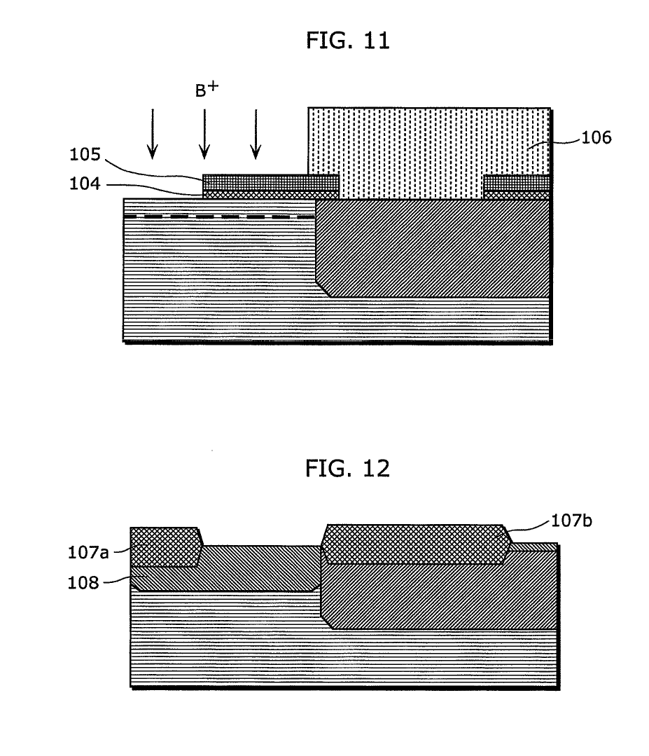

Next, an SiO₂ film 104 and an Si₃N₄ film 105 are formed. In a desired region, a resist pattern (not shown) is formed as a mask for etching the SiO₂ film 104 and the Si₃N₄ film 105. The SiO₂ film 104 and the Si₃N₄ film 105 are then patterned as shown in FIG. 11. Subsequently, a resist pattern 106 is formed and using it as a mask, B ions are implemented to the depth indicated by a dashed line in FIG. 11 so that the B ions pass through the SiO₂ film 104 and the Si₃N₄ film 105. The dose of the B ions is in the order of 2E12 cm⁻² to 5E12 cm⁻².

The resist pattern 106 is then removed and using the Si₃N₄ film 105 as a mask, SiO₂ films 107a and 107b are formed as shown in FIG. 12 through thermal oxidation so as to serve as insulator films for device separation, and the Si₃N₄ film 105 and the SiO₂ film 104 are removed. In this step of thermal oxidation, the B ions implanted in the step shown in FIG. 11 are diffused, with the result that a p-type dopant layer 108 serving as a base region is formed.

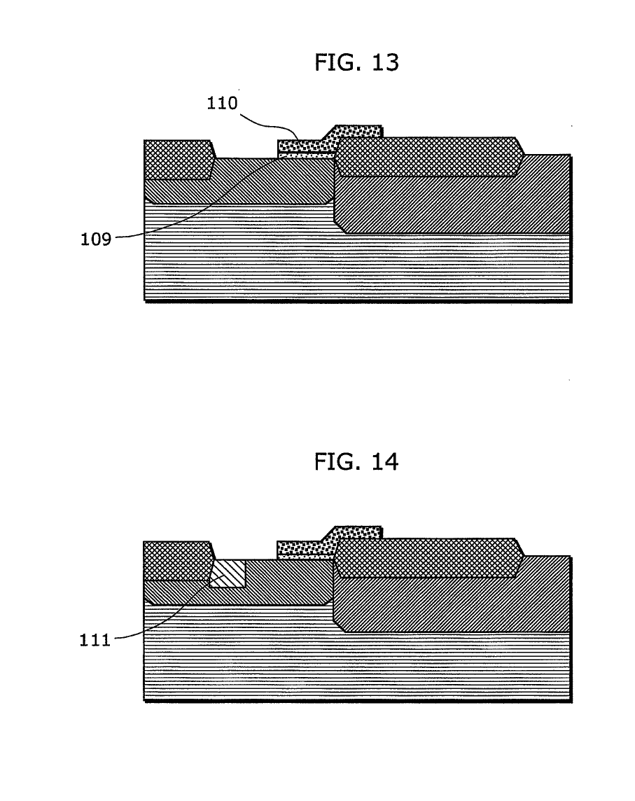

Next, as shown in FIG. 13, an SiO₂ film 109 and a poly-Si film 110 are formed, and using a resist pattern (not shown) as a mask, the poly-Si film 110 is etched and thereby patterned in a shape of an IGBT gate electrode.

Next, using a resist pattern (not shown) as a mask, B ions are implanted. The dose of the B ions is in the order of 1E15 cm⁻² to 5E15 cm⁻². Then, by removing the resist pattern, a p-type dopant layer 111 with a high concentration in the order of 1E18 cm⁻³ to 1E20 cm⁻³ and serving as a base connection region is formed as shown in FIG. 14.

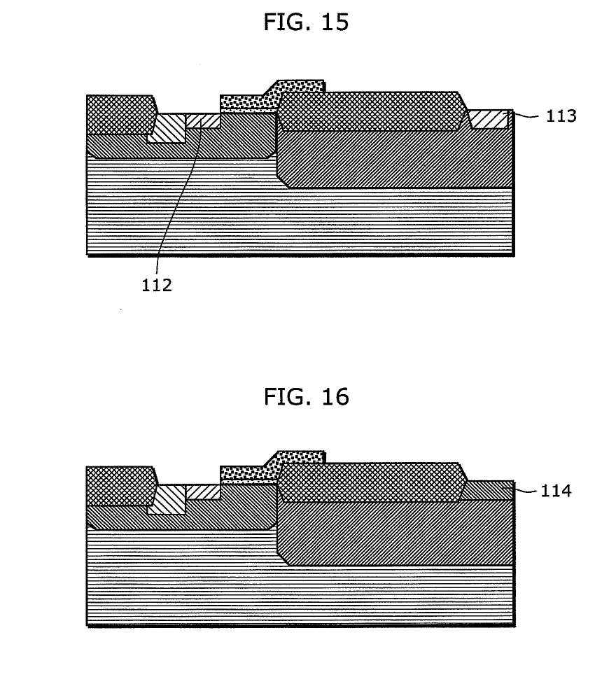

Next, using the poly-Si film pattern 110 and a resist pattern (not shown) as a mask, As ions are implanted. The dose of the As ions is in the order of 1E15 cm⁻² to 8E15 cm⁻². The resist pattern is then removed, and the structure is treated with heat in a nitrogen atmosphere of approximately 1,000° C. for around one to two hours, thereby forming n-type dopant layers 112 and 113 each having a high concentration in the order of 1E19 cm⁻³ to 1E21 cm⁻³ at a depth in the order of 0.8 μm as shown in FIG. 15. The n-type dopant layer 112 having the high concentration will serve as an emitter/source region, and the n-type dopant layer 113 having the high concentration will serve as a drain region.

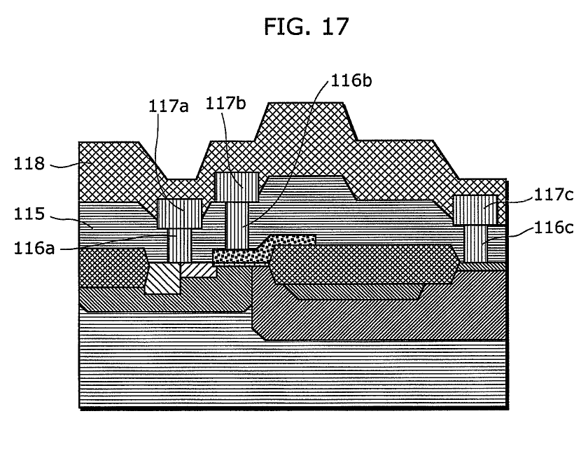

Next, using a resist pattern (not shown) as a mask, BF₂ ions are implanted. The dose of the BF₂ is in the order of 0.5E13 cm⁻² to 2E13 cm⁻². By removing the resist pattern, a p-type dopant layer 114 having a low concentration in the order of 1E17 cm⁻³ and serving as a collector region is formed as shown in FIG. 17.

Afterwards, a laminate film 15 of an SiO₂ film and a BPSG film, which will serve as an inter-layer insulator film, is deposited and then treated with heat at temperature of approximately 900° C. so as to have a flat surface. At this point of time, the p-type dopant layer 114 having the low concentration and serving as the collector region is diffused to have a depth in the order of 0.4 μm to 0.7 μm. Because the n-type dopant layer 113 having the high concentration and serving as the drain region has the depth in the order of 0.8 μm, the collector region is shallower than the drain region.

Subsequently, using a resist pattern (not shown) as a mask, the inter-layer insulator film 115 in a desired region is etched to form contact holes 116a, 116b, and 116c.

Next, in a sputtering device, an alloy film made primarily of Al such as AlSiCu is formed and etched using a resist pattern (not shown) as a mask. By removing the resist, Al alloy film patterns 117a, 117b, and 117c are formed as electrodes. Subsequently, an SiN film 118 serving as a protective film is formed by plasma CVD.

Through these steps, a power transistor having a lateral hybrid IGBD structure can be formed with the n-type dopant layer 103 having a low concentration and serving as a RESURF region, the p-type dopant layer 114 having a low concentration and serving as a collector region, and the n-type dopant layer having a high concentration and serving as a drain region.

Because the p-type dopant layer 114 (the collector region) having a low concentration formed in the n-type dopant layer 103 having a low concentration (the RESURF region) is shallower than the n-type dopant layer 113 having a high concentration (the drain region), it is possible to increase the fall speed of IGBT as described in the above first embodiment.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The present invention has an effect of increasing a switching speed of a switching device, particularly, a lateral IGBT, with a low on-resistance, and is useful for a semiconductor power device or the like.

What is claimed is:

1. A semiconductor device comprising:
a semiconductor substrate of a first conductivity type;
a RESURF region of a second conductivity type formed in a surface portion of said semiconductor substrate;
a base region of the first conductivity type formed in said semiconductor substrate so as to be adjacent to said RESURF region;
an emitter/source region of the second conductivity type formed in said base region so as to be isolated from said RESURF region;
a base connection region of the first conductivity type formed in said base region so as to be adjacent to said emitter/source region;
a gate insulator film formed on and across said emitter/source region, said base region, and said RESURF region;
a gate electrode formed on said gate insulator film;
a drain region of the second conductivity type formed in said RESURF region so as to be isolated from said base region;
a collector region of the first conductivity type formed in said RESURF region so as to be isolated from said base region and adjacent to said drain region;
a collector/drain electrode formed above said semiconductor substrate and electrically coupled to both of said collector region and said drain region; and
an emitter/source electrode formed above said semiconductor substrate and electrically coupled to both of said base connection region and said emitter/source region,
wherein said collector region is shallower than said drain region.

2. The semiconductor device according to claim 1,
wherein said collector region of the first conductivity type has a dopant concentration of 1.0×10¹⁷ cm⁻³ or less and a depth of 0.7 μm or less.

3. The semiconductor device according to claim 1,
wherein neither said RESURF region of the second conductivity type nor said semiconductor substrate of the first conductivity type has lattice damage for controlling a carrier life time.

4. A method of manufacturing a semiconductor device, comprising:
forming a RESURF region of a second conductivity type in a desired region in a surface of a semiconductor substrate of a first conductivity type;
forming a base region of a first conductivity type in the semiconductor substrate so as to be adjacent to the RESURF region;
laminating a gate insulator film and a gate electrode on part of the RESURF region and the base region;
forming an emitter/source region of the second conductivity type in a portion which is included in the base region and adjacent to the gate electrode;
forming a base connection region of the first conductivity type in a portion which is included in the base region and adjacent to the emitter/source region;
forming a drain region of the second conductivity type in a portion which is included in the RESURF region and isolated from the base region;
diffusing the drain region by a heat treatment;
forming a collector region of the first conductivity type in a portion which is included in the RESURF region, isolated from the base region, and adjacent to the drain region;
forming a collector/drain electrode so as to be electrically coupled to both of the collector region and the drain region; and
forming an emitter/source electrode so as to be electrically coupled to both of the base connection region and the emitter/source region,
wherein the collector region is formed to be shallower than the drain region.
